(19) United States
(12) Patent Application Publication
(10) Pub. No.: US 2026/0231811 A1
(43) Pub. Date: Aug. 6, 2026

(54) RELEASE FILM FOR MOLDING AND CHIP PACKAGING METHOD

(71) Applicant: NAN YA PLASTICS CORPORATION, TAIPEI (TW)

(72) Inventors: TE-CHAO LIAO, TAIPEI (TW); CHING-YAO YUAN, TAIPEI (TW); CHUN-CHE TSAO, TAIPEI (TW); Li-Yu Kao, TAIPEI (TW)

(21) Appl. No.: 19/207,680

(22) Filed: May 14, 2025

(30) Foreign Application Priority Data
Feb. 6, 2025 (TW) 114104256

(51) Int. Cl. H10W 74/01; B29C 33/62

(52) U.S. Cl. CPC H10W 74/017; B29C 33/62

(57) ABSTRACT

A release film for molding and a chip packaging method. The release film is adapted to be attached to a mold surface. The release film includes a substrate layer attached to the mold surface, and a release layer laminated on the substrate layer. A thickness ratio of the substrate layer to the release layer is within a range between 1:1 and 100:1. A coefficient of friction between the substrate layer and the mold surface is within a range between 0.19 and 0.23. A complex elastic modulus of the release film is within a range between 4 GPa and 8 GPa. The release film is used in one or more molding operations, and an encapsulating resin material is formed into a package that encapsulates a chip, so that an encapsulant having a smooth and burr-free appearance can be obtained.

### CROSS-REFERENCE TO RELATED PATENT APPLICATION

This application claims the benefit of priority to Taiwan Patent Application No. 114104256, filed on February 6, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a release film and its application, and more particularly to a release film for molding and a chip packaging method that adopts said release film.

### BACKGROUND OF THE DISCLOSURE

With the rapid development of technologies and ongoing expansion of end-user applications, demands for semiconductor chips are continuously increasing. In order to ensure that a chip is not affected by external factors (light, heat, water, gases, or physical impacts) and can function normally, a resin is used for packaging. During a chip packaging process, an encapsulating resin is formed into a package that encapsulates the chip by transfer molding or compression molding.

During a molding process, a carrier on which the semiconductor chip to be packaged is mounted is disposed in a mold cavity between upper and lower molds. The encapsulating resin (e.g., an epoxy resin) is filled into the mold cavity, so as to perform resin sealing of the chip. Since the encapsulating resin may stick to a mold surface when melting, a release film is often laid on the mold surface to prevent direct contact between a resin and the mold surface, thereby omitting a cleaning process that is required when the resin is stuck to the mold surface. In addition, the release film can enable the resin to be easily separated from the mold surface after curing.

However, when adhesion between a release surface of the release film and the mold surface (or a plate surface of a package side of the carrier) is poor, the resin is likely to leak out from a gap there-between, resulting in flaws such as uneven packaging or a poor package appearance (e.g., from generation of burr). Furthermore, when a high power component is used in an advanced process, a heat dissipation element is additionally encapsulated in a package segment. Hence, there is also the risk of adhesive leakage at a heterointerface between the heat dissipation element and the release film.

### SUMMARY OF THE DISCLOSURE

In response to the above-referenced technical inadequacies, the present disclosure provides a release film for molding. The release film can be well attached to a mold surface, so that an encapsulant having a smooth and burr-free appearance can be obtained. On this basis, the present disclosure further provides a chip packaging method, in which the release film is used in one or more molding operations.

In order to solve the above-mentioned problems, one of the technical aspects adopted by the present disclosure is to provide a release film for molding, which is adapted to be attached to a mold surface. The release film includes a substrate layer attached to the mold surface and a release layer formed on the substrate layer. In the present disclosure, a thickness ratio of the substrate layer to the release layer is within a range between 1:1 and 100:1, a coefficient of friction between the substrate layer and the mold surface is within a range between 0.19 and 0.23, and a complex elastic modulus of the release film is within a range between 4 GPa and 8 GPa.

In one of the possible or preferred embodiments, a material of the release layer contains an acrylic resin, and a material of the substrate layer contains a polyester resin.

In one of the possible or preferred embodiments, a glass transition temperature of the acrylic resin ranges between -60°C and -20°C, and a glass transition temperature of the polyester resin ranges between 60°C and 90°C.

In one of the possible or preferred embodiments, the acrylic resin is a copolymer of butyl methacrylate and butyl acrylate, and the polyester resin is polyethylene terephthalate.

In one of the possible or preferred embodiments, a total thickness of the release film ranges between 25 μm and 100 μm.

In one of the possible or preferred embodiments, when the release film is measured at 175°C according to JIS K7127 standards, a tensile breaking strength of the release film along a length direction ranges between 1,000 MPa and 1,200 MPa.

In one of the possible or preferred embodiments, when the release film is measured at 175°C according to JIS K7127 standards, a tensile elongation at break of the release film along a length direction ranges between 200% and 220%.

In order to solve the above-mentioned problems, another one of the technical aspects adopted by the present disclosure is to provide a chip packaging method. The chip packaging method includes: providing a mold assembly, in which the mold assembly includes a first mold and a second mold that are disposed opposite to each other, the first mold has a first mold surface, the second mold has a second mold surface, and a forming cavity is defined between the first mold surface and the second mold surface; arranging a carrier on which a chip to be packaged is mounted onto the first mold surface, aligning the carrier with the forming cavity, and attaching the above-mentioned release film to the second mold surface; placing an encapsulating resin material into the forming cavity; and closing the first mold and the second mold to perform a molding operation, so that the encapsulating resin material is formed into a package that encapsulates the chip.

In one of the possible or preferred embodiments, the process of placing the encapsulating resin material into the forming cavity further includes: arranging a heat dissipation member onto the release layer, and aligning the heat dissipation member with the forming cavity. In the molding operation, the heat dissipation member is bonded onto the package, and corresponds in position to the chip.

In one of the possible or preferred embodiments, during the molding operation, a minimum melt viscosity of the encapsulating resin material at 140°C is 34,000 cps, and a spiral flow length of the encapsulating resin material is measured to range between 160 cm and 200 cm according to ASTM D3123 standards.

Therefore, in the release film for molding and the chip packaging method provided by the present disclosure, the thickness ratio of the substrate layer to the release layer is controlled within the range between 1:1 and 100:1, the coefficient of friction between the substrate layer and the mold surface is controlled within the range between 0.19 and 0.23, and the complex elastic modulus of the release film is controlled within the range between 4 GPa and 8 GPa, thereby enabling the release film to be adapted to an undulating shape of the mold surface in the molding operation and to be completely attached to the mold surface (without blind corners and attachment gaps). Accordingly, stable and reliable performance can be obtained.

Furthermore, the release film of the present disclosure can be easily deformed along with the shape of the mold surface, and a matching degree between the release film and the mold surface is sufficient enough to achieve a tight sealing effect, so as to prevent the encapsulating resin material from leaking out of a mold in the molding operation and ensure that the encapsulant has excellent appearance and performance.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a release film for molding according to the present disclosure;

FIG. 2 is a flowchart of a chip packaging method according to the present disclosure;

FIG. 3 is a schematic view of a molding operation of the chip packaging method according to the present disclosure; and

FIG. 4 is a schematic view of an encapsulant obtained by the chip packaging method according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### Release Film for Molding

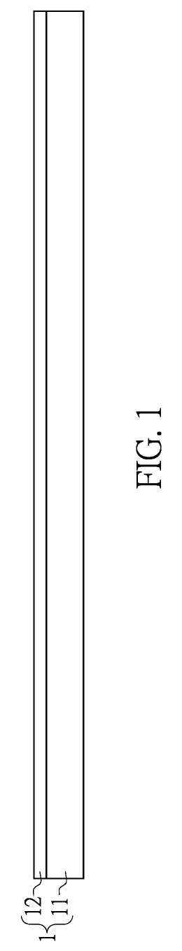

Reference is made to FIG. 1, which shows a release film 1 for molding according to one embodiment of the present disclosure. As shown in FIG. 1, the release film 1 of the present disclosure includes a substrate layer 11 and a release layer 12 laminated on the substrate layer 11. The release film 1 of the present disclosure is used for molding of various resins, which can be, for example but not limited to, compression molding of an epoxy resin or a silicone resin. Specifically, the release film 1 of the present disclosure is adapted to be attached to a mold surface, so as to prevent an encapsulating resin material from sticking to the mold surface and enable a package formed by the encapsulating resin material to be easily separated from the mold surface.

It should be noted that, by controlling a complex elastic modulus of the release film 1, a thickness ratio of the substrate layer 11 to the release layer 12, and a coefficient of friction between the substrate layer 11 and the mold surface in the present disclosure, the release film 1 can be adapted to an undulating shape of the mold surface in a molding operation, and can be completely attached to the mold surface (without blind corners and attachment gaps). Accordingly, stable and reliable performance can be obtained.

In the present disclosure, the thickness ratio of the substrate layer 11 to the release layer 12 is within a range between 1:1 and 100:1, such as 90:1, 80:1, 70:1, 60:1, 50:1, 40:1, 30:1, 20:1, 10:1, or an even lower ratio. The coefficient of friction between the substrate layer 11 and the mold surface is within a range between 0.19 and 0.23 at 25℃ according to ASTM D1894 standards. The complex elastic modulus of the release film 1 is within a range between 4 GPa and 8 GPa at 25℃ according to ASTM D5026 standards, and includes elastic moduli of elastic deformation of the substrate layer 11 and elastic deformation of the release layer 12.

When the release film 1 of the present disclosure is measured at 175°C according to JIS K7127 standards, a tensile breaking strength of the release film 1 along a length direction ranges between 1,000 MPa and 1,200 MPa, and a tensile elongation at break of the release film 1 along the length direction ranges between 200% and 220%.

A total thickness of the release film 1 of the present disclosure ranges between 25 μm and 100 μm, preferably ranges between 38 μm and 75 μm, and more preferably ranges between 40 μm and 65 μm, so as to enhance the followability of the release film 1 with respect to the mold surface. That is, the release film 1 is more likely to be deformed along with the shape of the mold surface.

The substrate layer 11 is formed by using a material containing a polyester resin as a main component. For example, based on a total weight of the material for forming the substrate layer 11 being 100 wt%, a content of the polyester resin can be greater than 50 wt%, 75 wt%, or 90 wt%. The polyester resin can be a homopolymer resin or a copolymer resin. In practical application, the substrate layer 11 can be a polyester substrate layer that is uniaxially or biaxially stretched, and is preferably a polyester substrate layer that is biaxially stretched.

In order to control the coefficient of friction between the substrate layer 11 and the mold surface to be within the range mentioned above, an appropriate amount of particles (e.g., inorganic or organic particles) can be mixed into the material for forming the substrate layer 11 when necessary. No specific limitations are placed on the type, the shape, and the size of the particles to be used. The particles to be used can be selected according to practical requirements, such as spherical silicon dioxide having an average particle size of below 5 μm.

Representative examples of the homopolymer resin include polyethylene terephthalate (PET) and polybutylene terephthalate (PBT). Representative examples of the copolymer resin include copolymers of terephthalic acid, ethylene glycol, and other comonomers. The comonomers can be a dicarboxylic acid component or a diol component. The dicarboxylic acid component is selected from one or more than one of the following dicarboxylic acids: isophthalic acid, phthalic acid, terephthalic acid, 2,6-naphthalic acid, adipic acid, and sebacic acid. The diol component is selected from one or more than one of the following diols: ethylene glycol, diethylene glycol, propylene glycol, 1,4-butanediol, 1,4-cyclohexanedimethanol, and neopentyl glycol. However, the present disclosure is not limited to these examples.

In an exemplary embodiment, the substrate layer 11 is formed by polyethylene terephthalate having a glass transition temperature of between 60°C and 90°C. This is beneficial for enhancing a matching degree between the release film 1 and the mold surface to achieve a tight sealing effect, so as to prevent the encapsulating resin material from leaking out of a mold in the molding operation and ensure that an encapsulant has excellent appearance and performance.

The release layer 12 is formed by using a material containing an acrylic resin as a main component. For example, based on a total weight of the material for forming the release layer 12 being 100 wt%, a content of the acrylic resin can be greater than 50 wt%, 75 wt%, or 90 wt%. The acrylic resin can be a homopolymer resin or a copolymer resin. In practical application, the material for forming the release layer 12 is coated onto one surface of the substrate layer 11, and is cured by heating. However, the present disclosure is not limited thereto.

A molecular weight of the acrylic resin ranges between 500,000 and 1,500,000, preferably ranges between 80,000 and 120,000, and more preferably ranges between 90,000 and 110,000. Monomer components for forming the acrylic resin can include at least one of an acrylate monomer and a methacrylate monomer. The acrylate monomer is selected from one or more than one of the following monomers: methyl acrylate, ethyl acrylate, propyl acrylate, iso-propyl acrylate, butyl acrylate, 2-hexyl acrylate, etc. The methacrylate monomer is selected from one or more than one of the following monomers: methyl methacrylate, ethyl methacrylate, propyl methacrylate, isopropyl methacrylate, butyl methacrylate, cyclohexyl methacrylate, phenyl methacrylate, benzyl methacrylate, etc. However, the present disclosure is not limited to these examples.

In an exemplary embodiment, the acrylic resin is a copolymer of butyl methacrylate and butyl acrylate (poly(BMA-co-BA), and has a glass transition temperature of between -60°C and -20°C. It should be noted that the copolymer of butyl methacrylate and butyl acrylate (poly(BMA-co-BA) is less likely to have a reaction with an encapsulating resin (e.g., an epoxy resin). Due to a low glass transition temperature (Tg), the hardness of a coating layer can be decreased during a packaging process, and the coating layer can be tightly attached to a carrier, a chip to be packaged, and the mold, thereby preventing leakage of the encapsulating resin. Accordingly, the release layer 12 has good performance in terms of releasing property, adhesion, and heat resistance.

### Chip Packaging Method

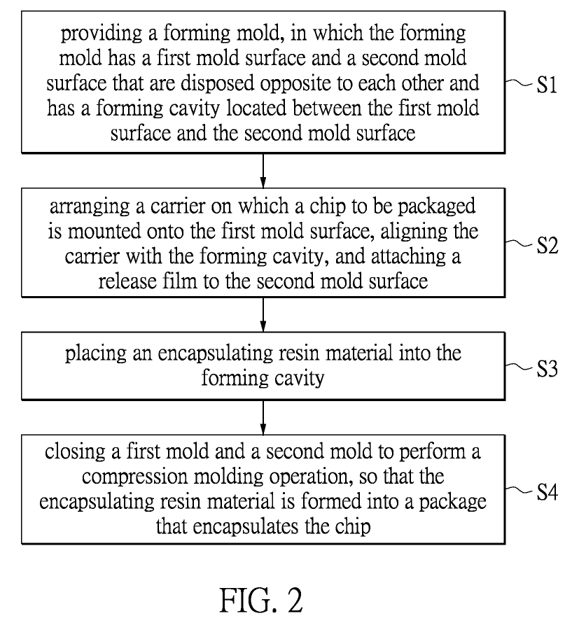

Reference is made to FIG. 2, which shows steps in a chip packaging method according to one embodiment of the present disclosure. The chip packaging method of the present disclosure uses the above-mentioned release film in one or more molding operations, and the encapsulating resin material is formed into the package that encapsulates the chip to be packaged.

As shown in FIG. 2, the chip packaging method of the present disclosure includes: providing a forming mold, in which the forming mold has a first mold surface and a second mold surface that are disposed opposite to each other and has a forming cavity located between the first mold surface and the second mold surface (step S1); arranging the carrier on which the chip to be packaged is mounted onto the first mold surface, aligning the carrier with the forming cavity, and attaching the release film to the second mold surface (step S2); placing the encapsulating resin material into the forming cavity (step S3); and closing a first mold and a second mold to perform the molding operation, so that the encapsulating resin material is formed into the package that encapsulates the chip.

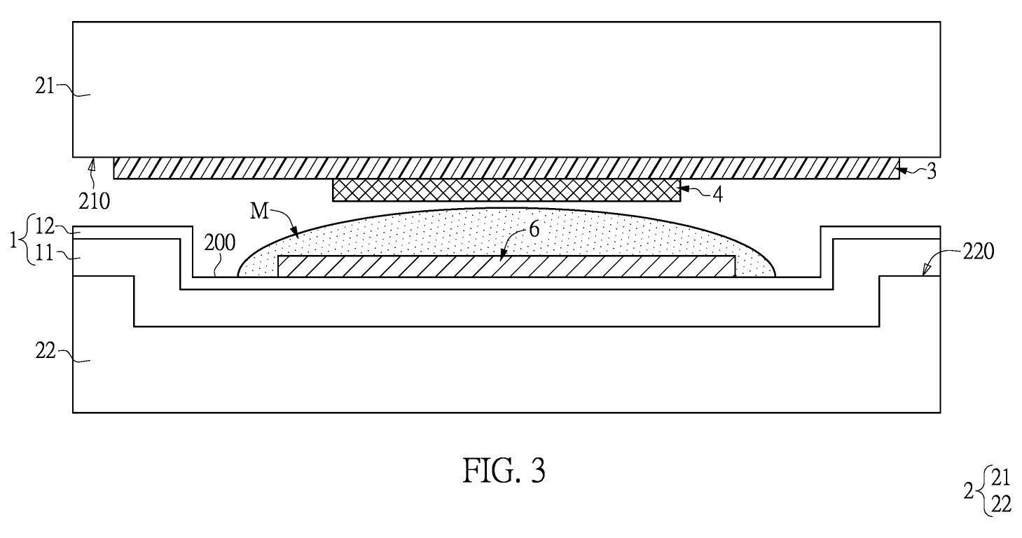

As shown in FIG. 3, a forming mold 2 includes a first mold 21 and a second mold 22 disposed opposite to each other. For example, the first mold 21 is an upper mold, and the second mold 22 is a lower mold. The forming mold 2 can be arranged on a packaging machine (not shown in the drawings). During closing or opening of the first mold 21 and the second mold 22, the second mold 22 can remain stationary, and the first mold 21 moves to be close to or away from the second mold 22. Alternatively, the first mold 21 can remain stationary, and the second mold 22 moves to be close to or away from the first mold 21. In addition, the first mold 21 has a first mold surface 210, the second mold 22 has a second mold surface 220, and a forming cavity 200 is defined between the first mold surface 210 and the second mold surface 220.

In practical application, during closing or opening of the first mold 21 and the second mold 22, an encapsulating resin material M is placed into the forming cavity 200. The encapsulating resin material M can be a liquid or granular resin material, and is arranged on the release film 1. However, the present disclosure is not limited thereto. Furthermore, conditions of the molding operation are as follows. A forming temperature (a mold temperature) ranges between 160°C and 190°C, a forming pressure ranges between 5 MPa and 12 MPa, and a forming time ranges between 5 minutes and 15 minutes. The presence of the release film 1 prevents the encapsulating resin material M from contacting the mold surface, and a formed piece can be easily removed from the forming mold 2.

As shown in FIG. 3, a heat dissipation member 6 (e.g., a heat sink) can be directly integrated with a product of the encapsulating resin material M during packaging, so as to satisfy heat dissipation requirements of the chip. Specifically, between step S2 and step S3, the heat dissipation member 6 is arranged on the release layer 12, and is aligned with the forming cavity 200. As such, in the molding operation, the heat dissipation member 6 can be bonded onto a package 5 that is formed by the encapsulating resin material M, and corresponds in position to a chip 4. It should be noted that, in order to prevent the encapsulating resin material M from leaking between the heat dissipation member 6 and the release layer 12, a minimum melt viscosity of the encapsulating resin material M at 140°C before thermosetting is 34,000 cps, and a spiral flow length of the encapsulating resin material M is measured to range between 160 cm and 200 cm according to ASTM D3123 standards.

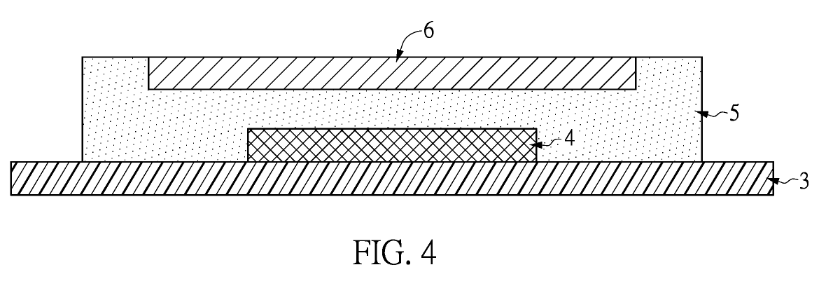

Referring to FIG. 4, the encapsulant obtained by the chip packaging method of the present disclosure includes a carrier 3, the chip 4, the package 5, and the heat dissipation member 6. The chip 4 is mounted on the carrier 3, the package 5 is formed on the carrier 3 and encapsulates the chip 4, and the heat dissipation member 6 and the package 5 are integrally formed.

### Beneficial Effects of the Embodiments

In conclusion, in the release film for molding and the chip packaging method provided by the present disclosure, the thickness ratio of the substrate layer to the release layer is controlled within the range between 1:1 and 100:1, the coefficient of friction between the substrate layer and the mold surface is controlled within the range between 0.19 and 0.23, and the complex elastic modulus of the release film is controlled within the range between 4 GPa and 8 GPa, thereby enabling the release film to be adapted to the undulating shape of the mold surface in the molding operation and to be completely attached to the mold surface (without blind corners and attachment gaps). Accordingly, stable and reliable performance can be obtained.

Furthermore, the release film of the present disclosure can be easily deformed along with the shape of the mold surface, and the matching degree between the release film and the mold surface is sufficient enough to achieve the tight sealing effect, so as to prevent the encapsulating resin material from leaking out of the mold in the molding operation and ensure that the encapsulant has excellent appearance and performance.

Furthermore, the release film of the present disclosure has excellent tensile properties. When the release film is measured at 175°C according to JIS K7127 standards, the tensile breaking strength of the release film along the length direction ranges between 1,000 MPa and 1,200 MPa, and the tensile elongation at break of the release film along the length direction ranges between 200% and 220%. Since the release film of the present disclosure can not only be repeatedly used in the molding operation for more than twice, but also maintains stable properties and will not break after multiple use, the costs for packaging can be decreased.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A release film for molding, adapted to be attached to a mold surface, the release film comprising:
a substrate layer attached to the mold surface; and
a release layer formed on the substrate layer;
wherein a thickness ratio of the substrate layer to the release layer is within a range between 1:1 and 100:1;
wherein a coefficient of friction between the substrate layer and the mold surface is within a range between 0.19 and 0.23; and
wherein a complex elastic modulus of the release film is within a range between 4 GPa and 8 GPa.

2. The release film according to claim 1, wherein a material of the release layer contains an acrylic resin, and a material of the substrate layer contains a polyester resin.

3. The release film according to claim 2, wherein a glass transition temperature of the acrylic resin ranges between -60°C and -20°C, and a glass transition temperature of the polyester resin ranges between 60°C and 90°C.

4. The release film according to claim 2, wherein the acrylic resin is a copolymer of butyl methacrylate and butyl acrylate, and the polyester resin is polyethylene terephthalate.

5. The release film according to claim 1, wherein a total thickness of the release film ranges between 25 μm and 100 μm.

6. The release film according to claim 1, wherein, when the release film is measured at 175°C according to JIS K7127 standards, a tensile breaking strength of the release film along a length direction ranges between 1,000 MPa and 1,200 MPa.

7. The release film according to claim 1, wherein, when the release film is measured at 175°C according to JIS K7127 standards, a tensile elongation at break of the release film along a length direction ranges between 200% and 220%.

8. A chip packaging method, comprising:
providing a mold assembly, wherein the mold assembly includes a first mold and a second mold that are disposed opposite to each other, the first mold has a first mold surface, the second mold has a second mold surface, and a forming cavity is defined between the first mold surface and the second mold surface;
arranging a carrier on which a chip to be packaged is mounted onto the first mold surface, aligning the carrier with the forming cavity, and attaching the release film as claimed in claim 1 to the second mold surface;
placing an encapsulating resin material into the forming cavity; and
closing the first mold and the second mold to perform a molding operation, so that the encapsulating resin material is formed into a package that encapsulates the chip.

9. The chip packaging method according to claim 8, wherein the process of placing the encapsulating resin material into the forming cavity further includes: arranging a heat dissipation member onto the release layer, and aligning the heat dissipation member with the forming cavity; wherein, in the molding operation, the heat dissipation member is bonded onto the package and corresponds in position to the chip.

10. The chip packaging method according to claim 9, wherein, in the molding operation, a minimum melt viscosity of the encapsulating resin material at 140°C is 34,000 cps, and a spiral flow length of the encapsulating resin material is measured to range between 160 cm and 200 cm according to ASTM D3123 standards.
